(19) United States
(12) Patent Application Publication
(10) Pub. No.: US 2017/0155043 A1
(43) Pub. Date: Jun. 1, 2017

(54) RESISTIVE RANDOM ACCESS MEMORY INCLUDING LAYER FOR PREVENTING HYDROGEN DIFFUSION AND METHOD OF FABRICATING THE SAME

(71) Applicant: Winbond Electronics Corp., Taichung City (TW)

(72) Inventor: Ming-Hung Hsieh, Taichung City (TW)

(21) Appl. No.: 15/062,220

(22) Filed: Mar. 7, 2016

(30) Foreign Application Priority Data
Nov. 26, 2015 (TW) 104139523

(51) Int. Cl. H01L 45/00

(52) U.S. Cl. CPC H01L 45/1253; H01L 45/1233; H01L 45/145; H01L 45/16

(57) ABSTRACT

A resistive random access memory is provided. The resistive random access memory includes a first electrode, a second electrode, a resistance changeable oxide layer, a hard mask layer, and a hydrogen barrier layer. The first electrode is disposed on a substrate. The second electrode is disposed between the first electrode and the substrate. The resistance changeable oxide layer is disposed between the first electrode and the second electrode. The hard mask layer is disposed on the first electrode. The hydrogen barrier layer is disposed between the hard mask layer and the first electrode.

### CROSS-REFERENCE TO RELATED APPLICATION

This application claims the priority benefit of Taiwan application serial no. 104139523, filed on Nov. 26, 2015. The entirety of the above-mentioned patent application is hereby incorporated by reference herein and made a part of this specification.

### BACKGROUND OF THE INVENTION

Field of the Invention

The invention relates to a non-volatile memory and a method of fabricating the same, and more particularly, to a resistive random access memory and a method of fabricating the same.

Description of Related Art

In general, in the fabrication process of a resistive random access memory, a lower electrode material layer, a resistance changeable oxide material layer, and an upper electrode material layer are first formed on a substrate in order, and then a patterned hard mask layer is formed on the upper electrode material layer to pattern the upper electrode material layer, the resistance changeable oxide material layer, and the lower electrode material layer. The patterned hard mask layer is generally formed by a plasma-enhanced chemical vapor deposition (PECVD) method in which silane (SiH₄) and oxygen gas are used as reaction gases, and therefore hydrogen ions readily remain in the formed patterned hard mask layer.

However, in the operation of the resistive random access memory, hydrogen ions in the patterned hard mask layer are diffused to a resistance changeable oxide layer through the upper electrode, such that the resistive switching behavior of the resistance changeable oxide layer is changed and thus the performance of the resistive random access memory is affected. More specifically, when a potential difference is applied to the resistive random access memory, hydrogen ions diffused from the patterned hard mask layer to the resistance changeable oxide layer affect the forming or breaking of a conductive filament inside the resistance changeable oxide layer, such that tailing bit effect is generated, and the resistive random access memory cannot be readily kept in a low-resistance state at high temperature. As a result, degradation of high-temperature data retention (HTDR) occurs.

Therefore, how to prevent diffusion of hydrogen ions in the patterned hard mask layer to the resistance changeable oxide layer is a current topic requiring investigation.

### SUMMARY OF THE INVENTION

The invention provides a resistive random access memory having a hydrogen barrier layer located between a hard mask layer and a resistance changeable oxide layer, wherein the hydrogen barrier layer can prevent diffusion of hydrogen ions in the hard mask layer to the resistance changeable oxide layer.

The invention provides a method of fabricating a resistive random access memory, wherein a hydrogen barrier layer is formed between a hard mask layer and a resistance changeable oxide layer to prevent diffusion of hydrogen ions in the hard mask layer to the resistance changeable oxide layer.

Based on the above, in the case that the hard mask layer of the invention contains hydrogen ions, diffusion of the hydrogen ions in the hard mask layer to the resistance changeable oxide layer can be prevented by the hydrogen barrier layer disposed between the hard mask layer and the first electrode, such that the hydrogen ions in the hard mask layer do not affect the resistive switching behavior of the resistance changeable oxide layer. Moreover, in the case that the hard mask layer of the invention is formed using a PVD method, the hard mask layer substantially does not contain hydrogen ions, such that the forming of the hard mask layer does not affect the resistive switching behavior of the resistance changeable oxide layer. Therefore, when a potential difference is applied to the resistive random access memory, a conductive filament in the resistance changeable oxide layer can be successfully formed or broken, and the generation of tailing bit effect can be prevented as a result. Moreover, high-temperature data retention characteristics, durability, and yield of the resistive random access memory can be improved.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are cross-sectional schematics of the fabrication process of the resistive random access memory of the first embodiment of the invention.

FIG. 2A to FIG. 2D are cross-sectional schematics of the fabrication process of the resistive random access memory of the second embodiment of the invention.

### DESCRIPTION OF THE EMBODIMENTS

Figures are provided in the present specification to more fully portray the concept of the invention, and embodiments of the invention are illustrated in the figures. However, the invention can also adopt many different forms for implementation, and the invention should not be construed as limited to the following embodiments. In actuality, the provided embodiments are only intended to make the invention more thorough and complete, and to fully convey the scope of the invention to those having ordinary skill in the art.

In the figures, for clarity, the size and the relative size of each layer and each region may be exaggerated.

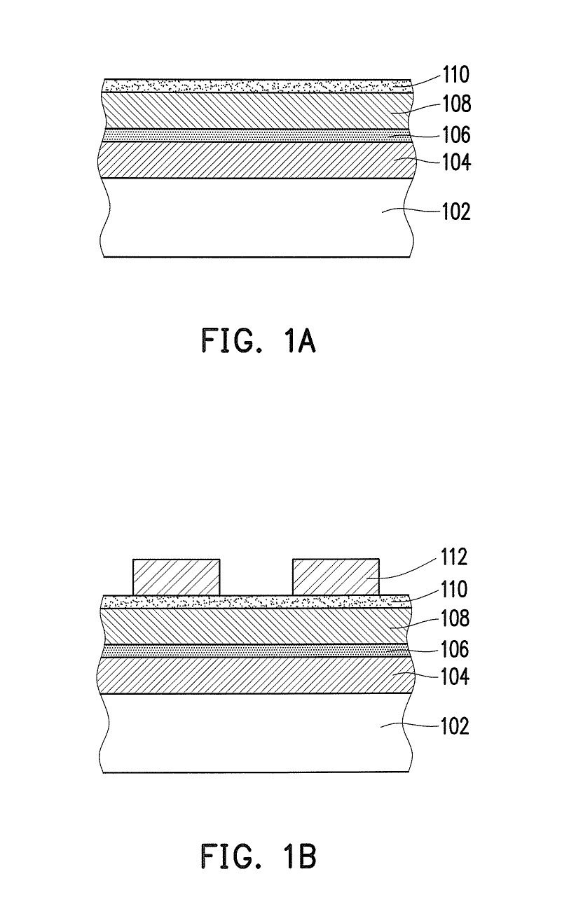

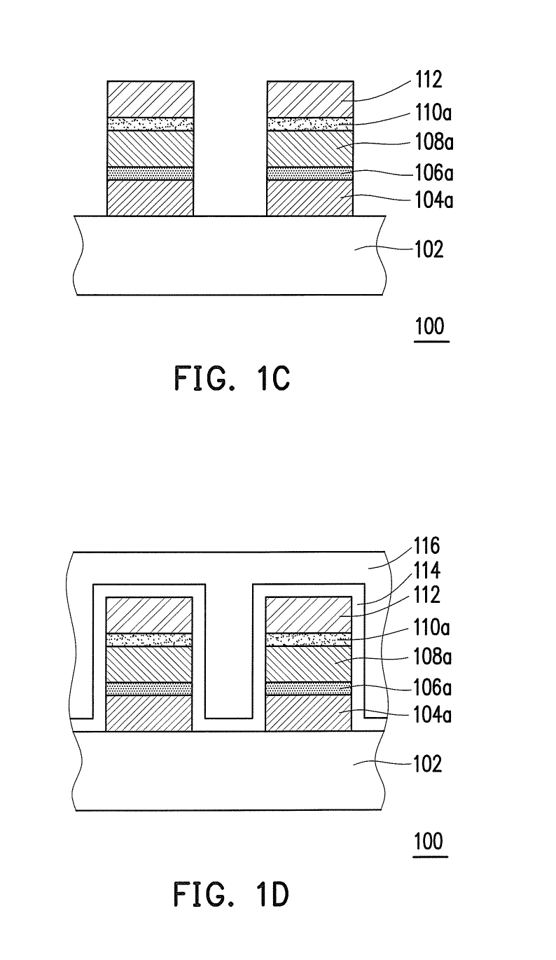

First, referring to FIG. 1A, an electrode material layer 104 is formed on a substrate 102. The substrate 102 is a dielectric substrate. In the present embodiment, the substrate 102 is not particularly limited. For instance, the substrate 102 is, for instance, composed of a silicon substrate and a dielectric layer located on the silicon substrate. Moreover, the silicon substrate can have a semiconductor device thereon, and the dielectric layer can have an interconnect structure therein. The material of the electrode material layer 104 is, for instance, titanium nitride (TiN) or titanium (Ti). The forming method of the electrode material layer 104 is, for instance, a physical vapor deposition (PVD) method or an atomic layer deposition (ALD) method.

Then, a resistance changeable oxide material layer 106 is formed on the electrode material layer 104. The material of the resistance changeable oxide material layer 106 is, for instance, transition metal oxide. The transition metal oxide is, for instance, hafnium oxide (HfO₂), tantalum oxide (Ta₂O₅), or other suitable metal oxides. The forming method of the resistance changeable oxide material layer 106 is, for instance, a PVD method or an ALD method. The resistance changeable oxide material layer 106 can have the following characteristics: when a positive bias is applied to the resistance changeable oxide material layer 106, oxygen ions leave the resistance changeable oxide material layer 106 due to the attraction of the positive bias such that oxygen vacancy is generated, a conductive filament is formed, and the conductive filament is in a conductive state, and as a result, the resistance changeable oxide material layer 106 is converted from a high-resistance state (HRS) to a low-resistance state (LRS); when a negative bias is applied to the resistance changeable oxide material layer 106, oxygen ions return to the resistance changeable oxide material layer 106, such that the conductive filament is broken and is in a non-conductive state, and the resistance changeable oxide material layer 106 is converted from an LRS to an HRS.

Then, an electrode material layer 108 is formed on the resistance changeable oxide material layer 106. The material of the electrode material layer 108 is, for instance, TiN, tantalum nitride (TaN), Ti, or Ta. The forming method of the electrode material layer 108 is, for instance, a PVD method or an ALD method.

Then, a hydrogen barrier material layer 110 is formed on the electrode material layer 108. The hydrogen barrier material layer 110 has good hydrogen ion barrier characteristics. The material of the hydrogen barrier material layer 110 is, for instance, metal oxide. The metal oxide is, for instance, aluminum oxide, titanium oxide, or iridium oxide. The forming method of the hydrogen barrier material layer 110 includes, for instance, performing a PVD process or an ALD process. The thickness of the hydrogen barrier material layer 110 is, for instance, between 5 nm and 100 nm.

Referring to FIG. 1B, a patterned hard mask layer 112 is formed on the hydrogen barrier material layer 110. The material of the patterned hard mask layer 112 is, for instance, silicon nitride, silicon oxynitride, silicon carbide, or silicon carbon nitride. In the present embodiment, the forming method of the patterned hard mask layer 112 includes a plasma-enhanced chemical vapor deposition (PECVD) method in which silane and oxygen gas are used as reaction gases. Therefore, hydrogen ions remain in the formed patterned hard mask layer 112. The thickness of the patterned hard mask layer 112 is, for instance, between 50 nm and 200 nm.

Referring to FIG. 1C, an etching process is performed using the patterned hard mask layer 112 as a mask to remove a portion of the hydrogen barrier material layer 110, a portion of the electrode material layer 108, a portion of the resistance changeable oxide material layer 106, and a portion of the electrode material layer 104 to form a hydrogen barrier layer 110a, an electrode 108a, a resistance changeable oxide layer 106a, and an electrode 104a, so as to form the resistive random access memory 100. The etching process is, for instance, a dry etching process. The electrode 104a can be used as a lower electrode of the resistive random access memory 100. The electrode 108a can be used as an upper electrode of the resistive random access memory 100. It should be mentioned that, since the hydrogen barrier layer 110a between the electrode 108a and the patterned hard mask layer 112 has good hydrogen ion barrier characteristics, diffusion of hydrogen ions in the patterned hard mask layer 112 to the resistance changeable oxide layer 106a can be prevented.

Referring to FIG. 1D, a liner layer 114 is formed on the substrate 102. The material of the liner layer 114 is, for instance, dielectric material, such as silicon oxide. The forming method of the liner layer 114 is, for instance, CVD method. In the present embodiment, the liner layer 114 is conformally formed on the substrate 102. In other words, the liner layer 114 covers a stacked structure consisting of the electrode 104a, the resistance changeable oxide layer 106a, the electrode 108a, the hydrogen barrier layer 110a and the patterned hard mask layer 112. A dielectric layer 116 is formed on the substrate 102. The dielectric layer 116 covers the liner layer 114 and the stacked structure covered by the liner layer 114. The material of the dielectric layer 116 is, for instance, silicon oxide. The forming method of the dielectric layer 116 is, for instance, CVD method. In the present embodiment, the dielectric layer 116 is used to isolate the resistive random access memory 100 and a conductive layer formed by the subsequent process.

The resistive random access memory 100 of the present embodiment includes a substrate 102, an electrode 104a, a resistance changeable oxide layer 106a, an electrode 108a, a hydrogen barrier layer 110a, and a patterned hard mask layer 112. The electrode 108a is disposed on the substrate 102. The electrode 104a is disposed between the electrode 108a and the substrate 102. The resistance changeable oxide layer 106a is disposed between the electrode 108a and the electrode 104a. The patterned hard mask layer 112 is disposed on the electrode 108a. The hydrogen barrier layer 110a is disposed between the patterned hard mask layer 112 and the electrode 108a.

In the present embodiment, since the patterned hard mask layer 112 is formed by a PECVD method in which silane and oxygen gas are used as reaction gases, hydrogen ions remain in the formed patterned hard mask layer 112. However, since the hydrogen barrier layer 110a disposed between the patterned hard mask layer 112 and the electrode 108a can prevent diffusion of hydrogen ions in the patterned hard mask layer 112 to the resistance changeable oxide layer 106a, the resistive switching behavior of the resistance changeable oxide layer 106a may be free from the influence of the hydrogen ions. In other words, when a positive bias is applied to the resistive random access memory 100, a conductive filament in the resistance changeable oxide layer 106a can be successfully formed and be in an LRS, and when a negative bias is applied to the resistive random access memory 100, the conductive filament in the resistance changeable oxide layer 106a can also be successfully broken and be in an HRS, thus facilitating the prevention of the generation of tailing bit effect, and the high-temperature data retention characteristics, the durability, and the yield of the resistive random access memory 100 can be improved.

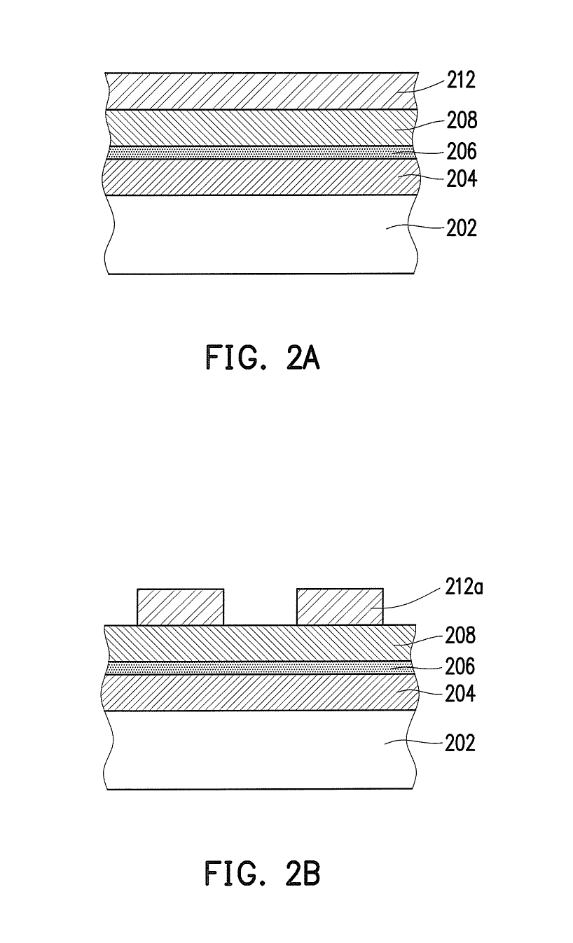

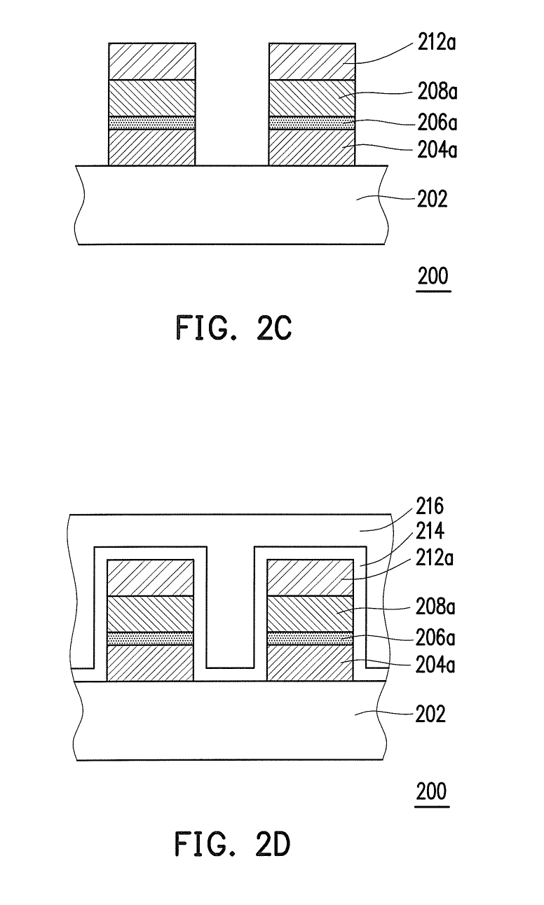

FIG. 2A to FIG. 2D are cross-sectional schematics of the fabrication process of the resistive random access memory of the second embodiment of the invention. A substrate 202, an electrode material layer 204, a resistance changeable oxide material layer 206, and an electrode material layer 208 of FIG. 2A are respectively similar to the substrate 102, the electrode material layer 104, the resistance changeable oxide material layer 106, and the electrode material layer 108 of FIG. 1A in terms of disposition, material, and forming method, and are therefore not repeated herein.

Referring to FIG. 2A, similarly to the method of FIG. 1A, the electrode material layer 204, the resistance changeable oxide material layer 206, and the electrode material layer 208 are formed on the substrate 202 in order. Then, a hard mask material layer 212 is formed on the electrode material layer 208. The material of the hard mask material layer 212 is, for instance, silicon nitride, silicon oxynitride, silicon carbide, or silicon carbon nitride. The forming method of the hard mask material layer 212 is, for instance, a PVD method. Since a hydrogen-containing gas is not used as a reaction gas in the PVD process as in the PECVD method, the hard mask material layer 212 formed by the PVD method substantially does not contain hydrogen ions. The above “substantially does not contain hydrogen ions” includes not containing hydrogen ions at all or a very small amount of hydrogen ions for which the content is close to 0. The thickness of the hard mask layer 212 is, for instance, between 50 nm and 200 nm.

Referring to FIG. 2B, the hard mask material layer 212 is patterned to form a patterned hard mask layer 212a.

Referring to FIG. 2C, an etching process is performed using the patterned hard mask layer 212a as a mask to remove a portion of the electrode material layer 208, a portion of the resistance changeable oxide material layer 206, and a portion of the electrode material layer 204 so as to form an electrode 208a, a resistance changeable oxide layer 206a, and an electrode 204a, so as to form a resistive random access memory 200. The etching process is, for instance, a dry etching process. The electrode 204a can be used as a lower electrode of the resistive random access memory 200. The electrode 208a can be used as an upper electrode of the resistive random access memory 200.

Referring to FIG. 2D, a liner layer 214 is formed on the substrate 202. The material of the liner layer 214 is, for instance, dielectric material, such as silicon oxide. The forming method of the liner layer 214 is, for instance, CVD method. In the present embodiment, the liner layer 214 is conformally formed on the substrate 202. In other words, the liner layer 214 covers a stacked structure consisting of the electrode 204a, the resistance changeable oxide layer 206a, the electrode 208a and the patterned hard mask layer 212a. A dielectric layer 216 is formed on the substrate 202. The dielectric layer 216 covers the liner layer 214 and the stacked structure covered by the liner layer 214. The material of the dielectric layer 216 is, for instance, silicon oxide. The forming method of the dielectric layer 216 is, for instance, CVD method. In the present embodiment, the dielectric layer 216 is used to isolate the resistive random access memory 200 and a conductive layer formed by the subsequent process.

The resistive random access memory 200 of the present embodiment includes: a substrate 202, an electrode 204a, a resistance changeable oxide layer 206a, an electrode 208a, and a patterned hard mask layer 212a. The electrode 208a is disposed on the substrate 202. The electrode 204a is disposed between the electrode 208a and the substrate 202. The resistance changeable oxide layer 206a is disposed between the electrode 208a and the electrode 204a. The patterned hard mask layer 212a is disposed on the electrode 208a.

In the present embodiment, since the patterned hard mask layer 212a is formed by performing a PVD method, the patterned hard mask layer 212a does not contain hydrogen ions (including the situation in which the content of a very small amount of hydrogen ions is close to 0). In the case that the patterned hard mask layer 212a does not contain hydrogen ions, the resistive switching behavior of the resistance changeable oxide layer 206a is not changed by the forming of the patterned hard mask layer 212a, and in the case in which the patterned hard mask layer 212a contains a very small amount of hydrogen ions for which the content is close to 0, even if the very small amount of hydrogen ions in the patterned hard mask layer 212a is diffused to the resistance changeable oxide layer 206a, the resistive switching behavior of the resistance changeable oxide layer 206a is still not affected. In other words, when a positive bias is applied to the resistive random access memory 200, a conductive filament in the resistance changeable oxide layer 206a can be successfully formed and be in an LRS, and when a negative bias is applied to the resistive random access memory 200, the conductive filament in the resistance changeable oxide layer 206a can also be successfully broken and be in an HRS, thus facilitating the prevention of the generation of tailing bit effect, and the high-temperature data retention characteristics, the durability, and the yield of the resistive random access memory 200 can be improved.

Of course, in other embodiments, the first embodiment and the second embodiment can also be combined. That is, a hard mask layer is formed by a PVD method and a hydrogen barrier layer can be formed between the resistance changeable oxide layer and the hard mask layer, so as to increase the margin and/or the degree of freedom of the process. Moreover, high-temperature data retention characteristics and durability can also be increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A resistive random access memory, comprising:
a first electrode disposed on a substrate;
a second electrode disposed between the first electrode and the substrate;
a resistance changeable oxide layer disposed between the first electrode and the second electrode, wherein the resistance changeable oxide layer is in contact with the first electrode;
a hard mask layer disposed on the first electrode; and
a hydrogen barrier layer disposed between the hard mask layer and the first electrode.

2. The resistive random access memory of claim 1, wherein a material of the hydrogen barrier layer comprises metal oxide.

3. The resistive random access memory of claim 2, wherein the metal oxide comprises aluminum oxide, titanium oxide, or iridium oxide.

4. The resistive random access memory of claim 1, wherein a thickness of the hydrogen barrier layer is between 5 nm and 100 nm.

5. A method of fabricating a resistive random access memory, comprising:
forming a first electrode on a substrate;
forming a second electrode between the first electrode and the substrate;
forming a resistance changeable oxide layer between the first electrode and the second electrode, wherein the resistance changeable oxide layer is in contact with the first electrode;
forming a hard mask layer on the first electrode; and
forming a hydrogen barrier layer between the hard mask layer and the first electrode.

6. The method of claim 5, wherein a material of the hydrogen barrier layer comprises metal oxide.

7. The method of claim 5, wherein a forming method of the hydrogen barrier layer comprises performing a physical vapor deposition (PVD) process or an atomic layered deposition (ALD) process.

8. A resistive random access memory, comprising:
a first electrode disposed on a substrate;
a second electrode disposed between the first electrode and the substrate;
a resistance changeable oxide layer disposed between the first electrode and the second electrode, wherein the resistance changeable oxide layer is in contact with the first electrode; and
a hard mask layer disposed on the first electrode, wherein the hard mask layer is formed by performing a PVD process.

9. The resistive random access memory of claim 8, wherein the hard mask layer does not contain hydrogen therein.

10. The resistive random access memory of claim 8, wherein a thickness of the hard mask layer is between 50 nm and 200 nm.
